(19) United States
(12) Patent Application Publication
(10) Pub. No.: US 2022/0269483 A1
(43) Pub. Date: Aug. 25, 2022

(54) COMPUTE IN MEMORY ACCUMULATOR

(71) Applicant: Taiwan Semiconductor Manufacturing Company, Ltd., Hsinchu (TW)

(72) Inventors: Chieh-Pu Lo, Hsinchu (TW); Po-Hao Lee, Hsinchu City (TW); Yi-Chun Shih, Taipei (TW)

(73) Assignee: Taiwan Semiconductor Manufacturing Company, Ltd., Hsinchu (TW)

(21) Appl. No.: 17/558,105

(22) Filed: Dec. 21, 2021

Related U.S. Application Data
(60) Provisional application No. 63/151,328, filed on Feb. 19, 2021.
(60) Provisional application No. 63/162,818, filed on Mar. 18, 2021.

(51) Int. Cl. G06F 7/525; G06F 7/544; G11C 11/412

(52) U.S. Cl. CPC G06F 7/525; G06F 7/5443; G11C 11/412; H03K 19/20

(57) ABSTRACT

A compute-in memory (CIM) device is configured to determine at least one input according to a type of an application and at least one weight according to a training result or a configuration of a user. The CIM device performs a bit-serial multiplication based on the input and the weight, from a most significant bit (MSB) of the input to a least significant bit (LSB) of the input to obtain a result according to a plurality of partial-products. A first partial-sum of a first bit of the input is left shifted one bit and then added with a second partial-product of a second bit of the input to obtain a second partial-sum of the second bit. The second bit is one bit after the first bit, and the result is output by the CIM device.

### CROSS-REFERENCE TO RELATED APPLICATIONS

This application claims the benefit of U.S. Provisional Patent Application No. 63/151,328, filed Feb. 19, 2021, entitled, “MULTIPLY AND ACCUMULATION DEVICE,” and U.S. Provisional Patent Application No. 63/162,818, filed Mar. 18, 2021, entitled, “MULTIPLY AND ACCUMULATION DEVICE.” The disclosure of these priority applications in their entirety are hereby incorporated by reference into the present application.

### BACKGROUND

This disclosure relates generally to in-memory computing, or compute-in-memory (“CIM”), and further relates to memory arrays used in data processing, such as multiply-accumulate (“MAC”) operations. Compute-in-memory or in-memory computing systems store information in the main random-access memory (RAM) of computers and perform calculations at memory cell level, rather than moving large quantities of data between the main RAM and data store for each computation step. Because stored data is accessed much more quickly when it is stored in RAM, compute-in-memory allows data to be analyzed in real time, enabling faster reporting and decision-making in business and machine learning applications. Efforts are ongoing to improve the performance of compute-in-memory systems.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the invention and are not intended to be limiting.

FIG. 1 is a block diagram illustrating an example of a compute-in-memory (CIM) device in accordance with some embodiments.

FIG. 2 is a schematic diagram illustrating an example of an SRAM memory cell used in the CIM device of FIG. 1 in accordance with some embodiments.

FIG. 3 is a schematic diagram illustrating an example of a memory cell and NOR gate used in the CIM device of FIG. 1 in accordance with some embodiments.

FIG. 4 is a schematic diagram illustrating an example of an SRAM memory cell and NOR gate coupled to a memory cell in the CIM device of FIG. 1 in accordance with some embodiments.

FIG. 5 is a schematic diagram illustrating an example of a memory cell and AND gate used in the CIM device of FIG. 1 in accordance with some embodiments.

FIG. 6 is a schematic diagram illustrating an example of an SRAM memory cell and AND gate coupled to a memory cell in the CIM device of FIG. 1 in accordance with some embodiments.

FIG. 7 is a block diagram illustrating a bit-serial multiply operation in accordance with some embodiments.

FIG. 8 is a block diagram illustrating further aspects of the bit-serial multiply operation shown in FIG. 7 in accordance with some embodiments.

FIG. 9 is a flow diagram illustrating an example of a method in accordance with some embodiments.

FIG. 10 is block diagram illustrating further aspects of the CIM device shown in FIG. 1 in accordance with some embodiments.

FIG. 11 is a block diagram illustrating a bit-serial multiply operation in accordance with some embodiments.

FIG. 12 is block diagram illustrating further aspects of the CIM device shown in FIG. 1 in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

This disclosure relates generally to computing-in-memory (“CIM”). An example of applications of CIM is multiply-accumulate (“MAC”) operations. Computer artificial intelligence (“AI”) uses deep learning techniques, where a computing system may be organized as a neural network. A neural network refers to a plurality of interconnected processing nodes that enable the analysis of data, for example. Neural networks compute “weights” to perform computation on new input data. Neural networks use multiple layers of computational nodes, where deeper layers perform computations based on results of computations performed by higher layers.

Machine learning (ML) involves computer algorithms that may improve automatically through experience and by the use of data. It is seen as a part of artificial intelligence. Machine learning algorithms build a model based on sample data, known as “training data” in order to make predictions or decisions without being explicitly programmed to do so.

Neural networks may include a plurality of interconnected processing nodes that enable the analysis of data to compare an input to such “trained” data. Trained data refers to computational analysis of properties of known data to develop models to use to compare input data. An example of an application of AI and data training is found in object recognition, where a system analyzes the properties of many (e.g., thousands or more) of images to determine patterns that can be used to perform statistical analysis to identify an input object.

As noted above, neural networks compute weights to perform computation on input data. Neural networks use multiple layers of computational nodes, where deeper layers perform computations based on results of computations performed by higher layers. Machine learning currently relies on the computation of dot-products and absolute difference of vectors, typically computed with MAC operations performed on the parameters, input data and weights. The computation of large and deep neural networks typically involves so many data elements it is not practical to store them in processor cache, and thus they are usually stored in a memory.

Thus, machine learning is very computationally intensive with the computation and comparison of many different data elements. The computation of operations within a processor is orders of magnitude faster than the transfer of data between the processor and main memory resources. Placing all the data closer to the processor in caches is prohibitively expensive for the great majority of practical systems due to the memory sizes needed to store the data. Thus, the transfer of data becomes a major bottleneck for AI computations. As the data sets increase, the time and power/energy a computing system uses for moving data around can end up being multiples of the time and power used to actually perform computations.

CIM circuits thus perform operations locally within a memory without having to send data to a host processor. This may reduce the amount of data transferred between memory and the host processor, thus enabling higher throughput and performance. The reduction in data movement also reduces energy consumption of overall data movement within the computing device.

In accordance with some disclosed embodiments, a CIM device includes a memory array with memory cells arranged in rows and columns. The memory cells are configured to store weight signals, and an input driver provides input signals. A multiply and accumulation (or multiplier-accumulator) circuit performs MAC operations, where each MAC operation computes a product of two numbers and adds that product to an accumulator (or adder). In some embodiments, a processing device or a dedicated MAC unit or device may contain MAC computational hardware logic that includes a multiplier implemented in combinational logic followed by an adder and an accumulator that stores the result. The output of the accumulator may be fed back to an input of the adder, so that on each clock cycle, the output of the multiplier is added to the accumulator. Example processing devices include, but are not limited to, a microprocessor, a digital signal processor, an application-specific integrated circuit, and a field programmable gate array.

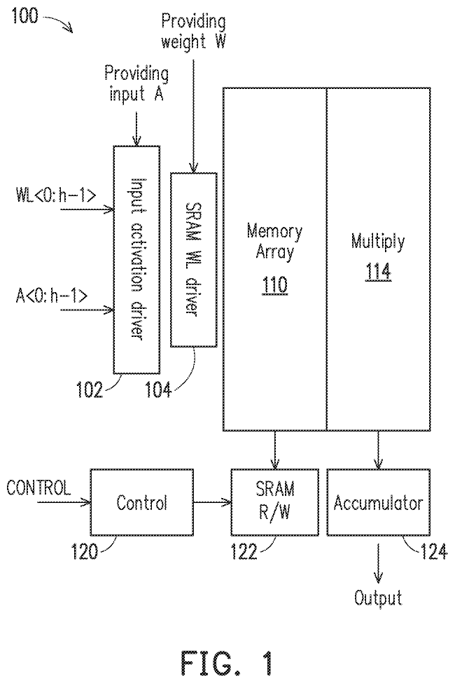

FIG. 1 is a block diagram illustrating an example CIM device 100 in accordance with the present disclosure. A CIM memory array 110 includes a plurality of memory cells configured to store weight signals W. The CIM memory array 110 can be implemented with a variety of memory devices, including static random-access memory (“SRAM”). In a typical SRAM device, data are written to, and read from, an SRAM cell via one or more bitlines (“BLs”) upon activation of one or more access transistors in the SRAM cell by enable-signals from one or more wordlines (“WLs”).

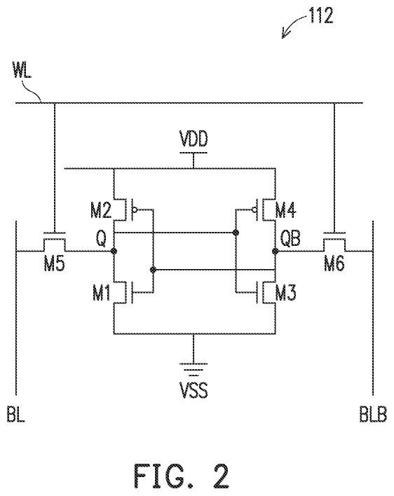

FIG. 2 is a circuit diagram illustrating an example memory cell 112 in accordance with some embodiments. The memory cell 112 includes but is not limited to a six-transistor (6T) SRAM cell 112. In some embodiments more or fewer than six transistors may be used to implement the SRAM cell 112. For example, the SRAM cell 112 in some embodiments may use a 4T, 8T or 10T SRAM structure, and in other embodiments may include a memory-like bit-cell or a building unit. The SRAM cell 112 includes a first inverter formed by a NMOS/PMOS transistor pair M1 and M2, and a second inverter formed by a NMOS/PMOS transistor pair M3 and M4, and access transistors/pass gates M5 and M6.

Power is supplied to each of the inverters, for example, a first terminal of each of transistors M2 and M4 is coupled to a power supply VDD, while a first terminal of each of transistors M1 and M3 is coupled to a reference Voltage VSS, for example, ground. A bit of data is stored in the SRAM cell 112 as a voltage level at the node Q, and can be read by circuitry via the bit line BL. Access to the node Q is controlled by the pass gate transistor M5. The node Qbar (QB) stores the complement to value at Q, e.g. if Q is “high,” QB will be “low,” and can be read by circuitry via the bit line BLbar (BLB). Access to QB is controlled by the pass gate transistor M6.

A gate of the pass gate transistor M5 is coupled to a word line WL. A first source/drain (S/D) terminal of the pass gate transistor M5 is coupled to the bit line BL, and a second S/D terminal of the pass gate transistor M5 is coupled to the second terminals of transistors M1 and M2 at the node Q. Similarly, a gate of the pass gate transistor M6 is coupled to the word line WL. A first S/D terminal of the pass gate transistor M6 is coupled to the complementary bit line BLB, and a second S/D terminal of the pass gate transistor M6 is coupled to second terminals of transistors M3 and M4 at the node QB.

Returning to FIG. 1, the CIM device 100 further includes an input driver 102 and a WL driver 104. The input driver 102 drives the input signals I that are multiplied by weights W stored in the memory array 110 by a multiply circuit 114. The WL driver outputs WL signals to activate the desired rows of memory cells. A memory controller 120 receives control inputs, and provides control signals to an SRAM read/write circuit 122 connected to the bitlines BL, BLB of the memory array 110 so as to select the appropriate bitlines BL, BLB (i.e. columns) corresponding to the stored weight W. The output signals from the multiply circuit 114 are provided to a partial sum accumulator circuit 124, which adds the partial sum outputs of the multiply circuit 110 as will be discussed further below.

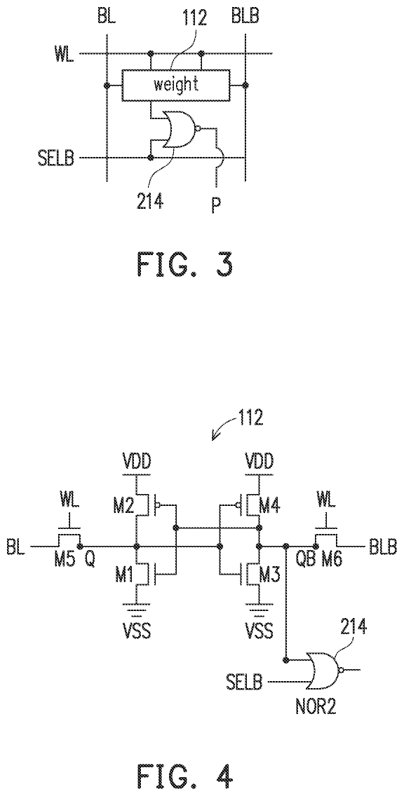

The multiply circuit 114 is configured to multiply the input signals I and the weights W. FIG. 3 illustrates an example in which the logic circuit 114 is a NOR gate 214 that receives the weight signal W from memory array 112, along with the input signal I in the form of an inverted select signal SELB to output a product P of the weight signal W and the select signal SELB. FIG. 4 illustrates further aspects of a disclosed embodiment where the memory cell is a 6T SRAM cell 112 as shown in FIG. 2 and discussed above, and the multiplier circuit 114 includes the two input NOR gate 214. One input of the NOR gate 214 is coupled to the node QB of the SRAM cell 212 to receive an inverted weight signal, while the other input of the NOR gate 214 receives the SELB signal.

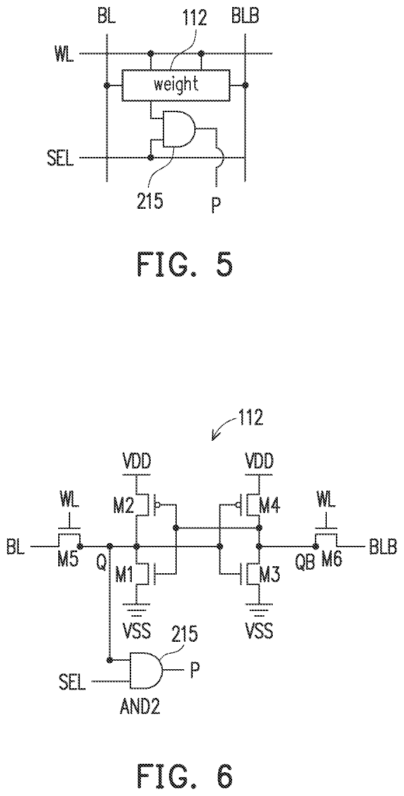

FIG. 5 illustrates another example in which the multiplier circuit 114 is an AND gate 215 that receives the weight signal W from the memory array 112, along with the input signal I in the form of a select signal SEL to output a product P of the weight signal W and the select signal SEL. FIG. 6 illustrates further aspects of a disclosed embodiment where the memory cell is the 6T SRAM cell 212 as shown in FIG. 2 and discussed above, and the multiplier circuit 114 includes the two input AND gate 215. One input of the AND gate 215 is coupled to the node Q of the SRAM cell 112 to receive the weight signal, while the other input of the AND gate 215 receives the SEL signal.

In some examples, the multiply circuit 114 is configured to perform a bit-serial multiplication of the input I and the weight W from a most significant bit of the input to a least significant bit of the input, thus producing a plurality of partial-products. The partial products are output to the accumulator 124, where a first partial-product corresponding to a first bit of the input I is left shifted one bit and then added with a second partial-product of a second bit of the input I, where the second bit is one bit after the first bit. This results in a first partial sum.

In contrast, conventional MAC operations implement multiply operations beginning with the least significant bit (LSB). As such, a partial-product for the LSB of the input I is produced, and is then left-shifted for the accumulation of partial-sums. This requires a large chip area to provide shifting circuits for each of the input bits. Further, the length of the input may be limited by the shifting circuits.

In accordance with disclosed embodiments, the accumulator 124 receives the partial-product inputs from the multiply circuit 114, where the first received input is a partial product of the most significant bit (MSB) of the input multiplied by the weight W. For example, the input data I may be represented by bits 0-N (i.e. an N+1 bit input, N>1), with the weight W represented by bits 0-X (i.e. an X+1 bit weight, X>1). The bit-serial MAC operation begins with the MSB of the input I, I[N]. Thus, the first partial-product is produced according to I[N]×W[X:0]. The second partial-product is produced according to I[N−1]×W[X:0]. In such an embodiment, the implementation is:

1st cycle I[N]×W[X:0]

2nd cycle I[N−1]×W[X:0]

3rd cycle I[N−2]×W[X:0]

N+1th cycle I[0]×W[X:0]

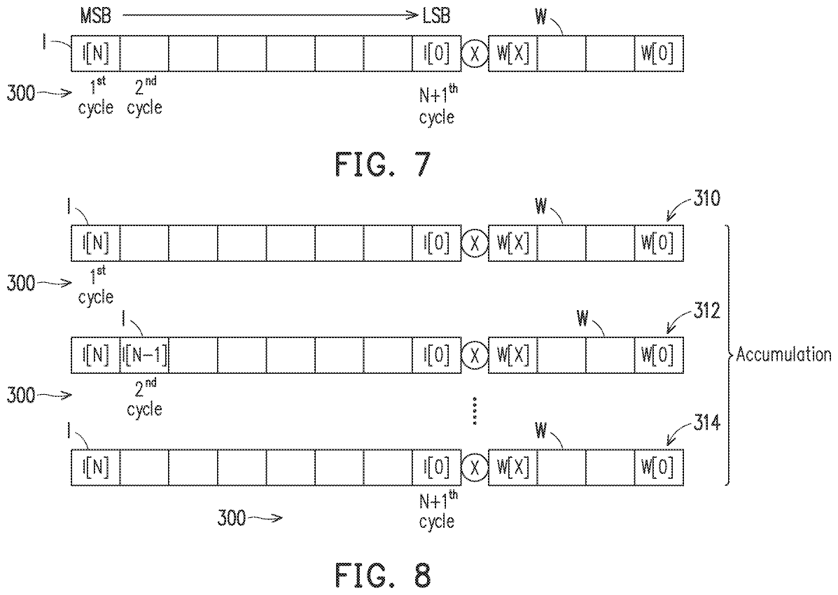

An example of such an implementation is shown in FIG. 7, illustrating the input I[N:0] and the weight W[X:0], with multiply cycles 300 corresponding to the input bits I[N:0]. Each bit I[N:0] of the input I is serially multiplied by the weight W[X:0], beginning with the MSB of the input I, e.g. I[N], and continuing through the input LSB I[0]. Thus, as shown in FIG. 8, during the first cycle the MSB of the input I[N] is multiplied by the weight W[X:0] to produce a first partial-product 310, during the second cycle the next bit I[N−1] is multiplied by the weight W[X:0] to produce a second partial-product 312, and so on until the N+1th cycle where the LSB of the input I[0] is multiplied by the weight W[X:0] to produce an N+1th partial-product 314. As will be discussed further below, the partial-products 310-314 are then added or accumulated by the accumulator 124.

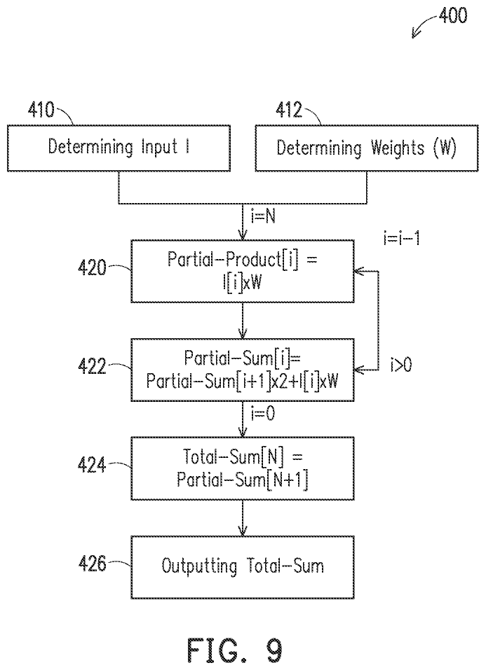

FIG. 9 is a flow chart illustrating a method 400 in accordance with disclosed embodiments. At operation 410, inputs I are determined, for example, based the AI application such as machine learning, neural networks, etc. Weights W are determined at operation 412, according to training data or a user's configuration, for example. The input and the weights are multiplied as shown in the example of FIGS. 7 and 8. As noted above, a bit-serial multiplication is performed in which each bit of the input I is multiplied by the weight W, resulting in a partial-product. More particularly, the bit-serial multiplication of the input I and the weight W are performed from a most significant bit MSB of the input I to a least significant bit LSB of the input I, generating a plurality of partial-products.

As with the examples discussed above, FIG. 9 assumes the input data I determined at operation 410 is represented by bits 0-N, i.e. I[N:0], and the weight W determined at operation 412 is represented by bits 0-X, i.e. W[X:0]. Initially, the multiply cycle i is set equal to N. Thus, the bit-serial MAC operation begins with the MSB of the input I[i]. The first partial-product partial-product[i] is produced according to I[i]×W[X:0] at operation 420. At operation 422, a partial-sum[i] is determined by left-shifting the previous partial-sum by one bit (i.e. Partial-SumI[i+1]×2¹), and adding the left-shifted previous partial-product to a second partial-product that is determined according to I[i+1]×W[X:0].

If i>0, then i is reduced by 1 (i.e. i=i−1) and the method 400 loops back to operation 420. Thus, a partial product is determined for the next input bit I[i−1] at operation 420. At operation 422, the partial-sum[i+1] is again determined by left-shifting the previous partial-product determined at operation 420 by one bit, and adding the left-shifted partial-sum to the partial-product determined according to I[i]×W[X:0]. Operations 420 and 422 are repeated until i=0, i.e., the partial product for the LSB of the input I is determined at operation 420 and the corresponding partial-sum is determined at operation 422.

When the partial-sum for the LSB (i=0) has been determined in operation 422, the partial-sum corresponding to the LSB of input I is converted to the total sum Total-Sum[N] in operation 424 and output in operation 426.

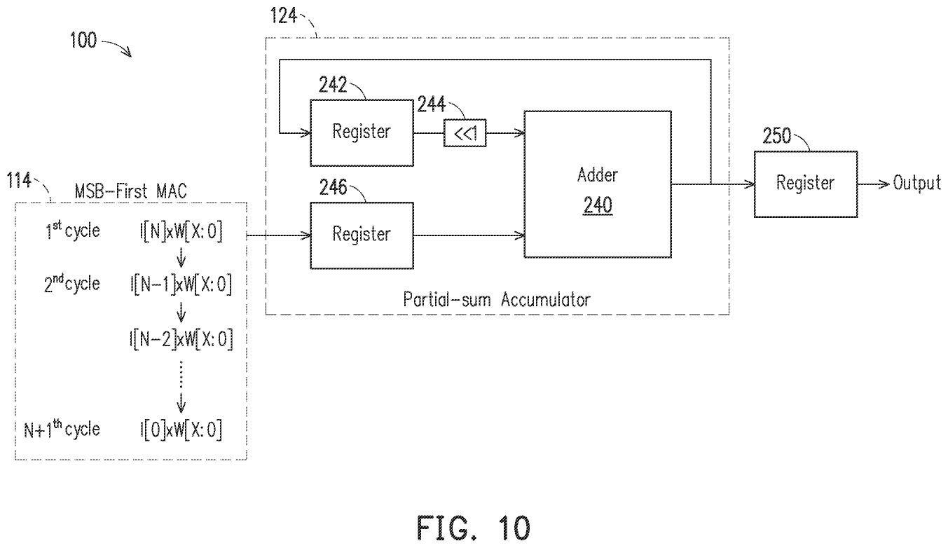

FIG. 10 is a block diagram illustrating an embodiment of the accumulator 124 of the CIM device 100. The accumulator 124 receives the partial-product outputs of the MSB-first multiply circuit 112, and the accumulator 124 implements the left-shift and partial-sum determination of operation 422 shown in FIG. 9. The accumulator 124 includes an adder 240 with a shifter 244 having an output operably connected to a first input of the adder 240. The shifter is configured to implement the left-shift of operation 424 of FIG. 9. A first register 242 has an output operably connected to an input of the shifter 244, and a second register 246 has an output operably connected to a second input of the adder 240.

The second register 246 receives the partial-product outputs of the multiplier 114. As noted above, the multiply circuit 114 is configured to perform a bit-serial multiplication of the input I and the weight W from the MSB to the LSB of the input I to output the partial-products that are received by the second register 246. Thus, the second register 246 initially receives the partial-product corresponding to the MSB of the input I multiplied by the weight W (i.e. i=N as shown in FIG. 9) during a first multiplication cycle i (1=N). The initial partial-product (partial-product[i]=I[i]×W[X:0]; i=N) is output from the second register 246 to the adder 240, which outputs the partial-product for the input I MSB to the first register 242. The shifter 244 left-shifts the partial-sum by one bit (i.e. partial-sum[i]=Partial-Sum[i+1]×2+I[i]×W), and the left-shifted partial-sum is output by the shifter 244 to the adder 240.

During the next cycle i−1, the adder 240 determines the partial-sum as shown in operation 422 of FIG. 9, by adding the left-shifted partial-sum output by the shifter 244 to the partial-product I[i]×W[X:0]. This is repeated for N+1 multiplication cycles as shown in FIGS. 7 and 8. Thus, when i=0 as shown in FIG. 9, the adder 240 outputs the total-sum according to total-sum[N]=partial-sum[N+1] in accordance with operations 424 and 426 of FIG. 9.

Thus, for the product of each bit of input I[N:0]×W[X:0] (i.e. each partial-product), each partial-sum is left-shifted one bit for the partial-sum before adding with the partial-product of the next bit (i.e. I[i1]×W[X:0]) from the MSB to the LSB of the input I. This effectively calculates the total sum according to

Total Sum=ΣI[i]×W×2ⁱ; i=N˜0

However, by determining the partial-product for the input I MSB first, the shifter 244 is able to accomplish the shifting operation for the total sum calculation. In contrast, conventional MAC implementations determining partial-product from LSB to MSB of the input may require a plurality of shifters and associated circuits for a corresponding plurality of shifting operations depending on the length of the input. This in turn, complicates the circuit design, requires additional chip space, consumes additional power, etc., and may result in a limited input length.

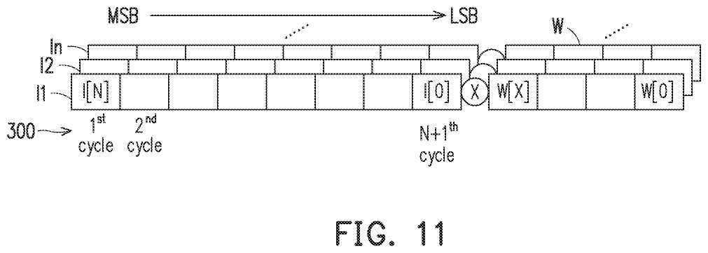

FIGS. 7 and 8 illustrate an example where partial-products for a single input I were accumulated by the accumulator 124. In other implementations, multiple inputs I may be generated by the input activation driver 102. FIG. 11 illustrates such an embodiment, in which a plurality of inputs I1-In are each multiplied by the weight W[X:0].

In FIG. 11, each of a plurality of inputs I1[N:0] . . . In[N:0] are multiplied by the weight W1[X:0] . . . Wn[X:0]. The multiply cycles 300 correspond to each bit [N:0] of the corresponding input I1 . . . In. Each bit [N:0] of each input I1 . . . . In is serially multiplied by the weight W1[X:0] . . . Wn[X:0], beginning with the MSB of each input I1 . . . In, and continuing through the input LSB I[0]. Thus, during the first cycle the MSB of each input I1 . . . In is multiplied by the weight W1[X:0] . . . Wn[X:0] to produce respective partial-products. During the second cycle the next input bits I[N−1] for each input I1 . . . In are multiplied by the corresponding weight W1[X:0] . . . Wn[X:0] to produce a second partial-product, and so on until the N+1th cycle where the LSB of the inputs I[0] are multiplied by the weight W[X:0] to produce an N+1th partial-product.

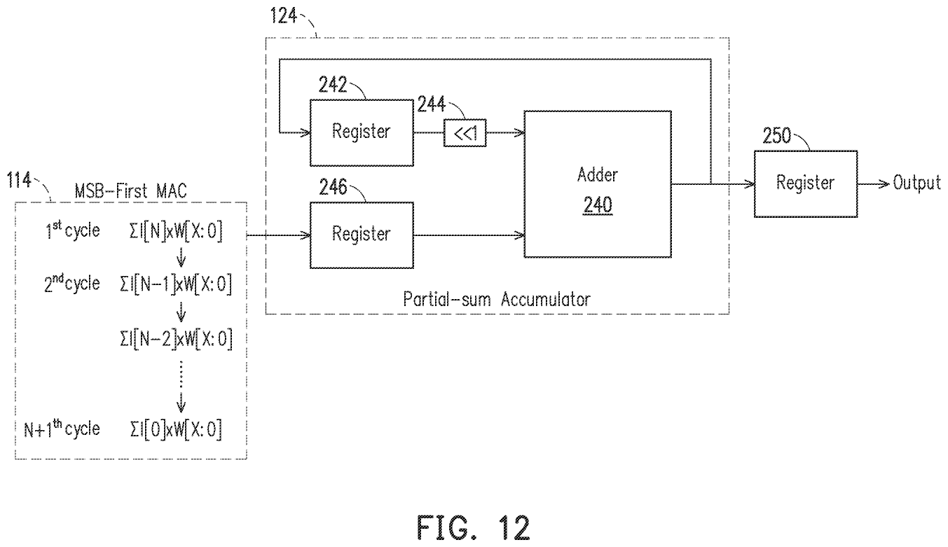

FIG. 12 illustrates an example of the accumulator 124 and multiply circuit 114. In the example of FIGS. 11 and 12, the partial-products produced during each multiply cycle are summed by the multiply circuit 114. The multiply circuit 114 may include, for example, an adder circuit for summing the partial-products for each of the inputs. The sum of each partial-product is then output by the multiply circuit 114 to the accumulator 124. As with the example of FIG. 10, the accumulator 124 shown in FIG. 12 receives the summed partial-product outputs of the multiply circuit 114 beginning with the summed partial-products corresponding to the MSB of the inputs I1 . . . In. The accumulator 124 is configured to implement the left-shift and partial-sum determination of operation 422 shown in FIG. 9.

The shifter 244 has its output operably connected to a first input of the adder 240, and the shifter is configured to implement the left-shift of operation 424 of FIG. 9. The first register 242 has its output operably connected to an input of the shifter 244, and a second register 246 has an output operably connected to a second input of the adder 240. The second register 246 receives the summed partial-product outputs of the multiplier 114. As noted above, the multiply circuit 114 is configured to perform a bit-serial multiplication of each of the inputs I1 . . . In and the weight W from the MSB to the LSB of the inputs to output the summed partial-products that are received by the second register 246. Thus, the second register 246 initially receives the summed partial-products corresponding to the MSB of the inputs I1 . . . In multiplied by the weight W (i.e. i=N as shown in FIG. 9) during a first multiplication cycle i (i=N). The initial partial-product (partial-product[i]=I[i]×W[X:0]; i=N) is output from the second register 246 to the adder 240, which outputs the partial-product for the input I MSB to the first register 242. The shifter 244 left-shifts the partial-product by one bit (i.e. partial-product[i]=I[i]×W[X:0]×2¹), and the left-shifted partial-product is output by the shifter 244 to the adder 240.

During the next cycle i−1, the adder 240 determines the partial-sum as shown in operation 422 of FIG. 9, by adding the left-shifted partial-product output by the shifter 244 to the partial-product I[i+1]×W[X:0]. This is repeated for N+1 multiplication cycles as shown in FIG. 11. Thus, when i=0 as shown in FIG. 9, the adder 240 outputs the total-sum according to total-sum[N]=partial-sum[N+1] in accordance with operations 424 and 426 of FIG. 9.

Disclosed embodiments thus include a computing method configured to perform bit-serial multiplication in a compute-in memory (CIM) device. The CIM device receives at least one input according to a type of an application and at least one weight according to a training result or a configuration of a user. The CIM device performs a bit-serial multiplication based on the input and the weight, from a most significant bit (MSB) of the input to a least significant bit (LSB) of the input to obtain a result according to a plurality of partial-products. A first partial-sum of a first bit of the input is left shifted one bit and then added with a second partial-product of a second bit of the input to obtain a second partial-sum of the second bit. The second bit is one bit after the first bit, and the result is output by the CIM device.

In accordance with further aspects, a CIM device includes an adder and a shifter having an output terminal operably connected to a first input terminal of the adder. The shifter is configured to left-shift one bit. A first register has an output terminal operably connected to an input terminal of the shifter. A second register has an output terminal operably connected to a second input terminal of the adder. A multiplier is configured to perform a bit-serial multiplication based on an input signal and a weight signal to obtain a plurality of partial-products. An input terminal of the second register is operable to receive a first one of the plurality of partial-products based on a most significant bit (MSB) of the input signal. An input terminal of the first register is operable to receive an output of the adder.

In accordance with still further disclosed aspects, a CIM device includes a memory array storing a weight signal. An input driver is configured to output an input signal. A multiplier is configured to perform a bit-serial multiplication of the input signal and the weight signal, from an MSB of the input signal to an LSB of the input signal to determine a plurality of partial-products. A shifter is configured to left-shift a first partial-sum of a first bit of the input signal one bit. An adder is configured to add the left-shifted first partial-sum and a second partial-product of a second bit of the input signal to obtain a second partial-product of the second bit, which is one bit after the first bit.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A computing method configured to perform bit-serial multiplication in a compute-in memory (CIM) device, the computing method comprising:
determining at least one input according to a type of an application;
determining at least one weight according to a training result or a configuration of a user;
performing a bit-serial multiplication based on the input and the weight, by the CIM device, from a most significant bit (MSB) of the input to a least significant bit (LSB) of the input to obtain a result according to a plurality of partial-products, wherein a first partial-sum of a first bit of the input is left shifted one bit and then added with a second partial-product of a second bit of the input to obtain a second partial-sum of the second bit, the second bit is one bit after the first bit; and
outputting the result, by the CIM device.

2. The method of claim 1, wherein performing the bit-serial multiplication comprises:
determining the first partial-product of the first bit by multiplying the MSB I[N] (N>0) of the input by each bit of the weight by a multiply circuit.

3. The method of claim 1, wherein the input comprises a plurality of inputs, and wherein performing the bit-serial multiplication comprises:
determining a plurality of the first partial-products for the first bit by multiplying the MSB of each of the inputs by each bit of the weight by a multiply circuit; and
summing the plurality of the first partial-products.

4. The method of claim 2, wherein performing the bit-serial multiplication comprises:
left-shifting the first partial product sum one bit by an accumulator circuit;
determining the second partial-product of the second bit by multiplying the next bit I[N−1] of the input by each bit of the weight by the multiply circuit.

5. The method of claim 4, wherein performing the bit-serial multiplication comprises:
adding the left-shifted first partial-sum and the second partial-product by the accumulator circuit to obtain the first partial-sum of the next bit I[N−1].

6. The method of claim 5, wherein performing the bit-serial multiplication comprises:
left-shifting the obtained first partial sum of the next bit I[N−1] one bit by the accumulator circuit;
determining the second partial-product of a second next bit I[N−2] by multiplying the second next bit I[N−2] of the input by each bit of the weight by the multiply circuit; and
adding the obtained left-shifted first partial sum of the next bit I[N−1] and the second partial-product of a second next bit I[N−2] by the accumulator circuit to obtain the first partial-sum of the second next bit I[N−2].

7. The method of claim 5, wherein performing the bit-serial multiplication comprises:
left-shifting the obtained first partial sum of the next bit I[N−1] one bit by the accumulator circuit;
determining the second partial-product of the LSB I[0] by multiplying the LSB I[0] of the input by each bit of the weight by the multiply circuit; and
adding the obtained left-shifted first partial sum of the next bit I[N−1] and the second partial-product of the LSB I[0] by the accumulator circuit to obtain the total-sum.

8. A device, comprising:
an adder;
a shifter having an output terminal operably connected to a first input terminal of the adder, the shifter configured to left-shift one bit;
a first register having an output terminal operably connected to an input terminal of the shifter;
a second register having an output terminal operably connected to a second input terminal of the adder;
a multiplier configured to perform a bit-serial multiplication based on an input signal and a weight signal to obtain a plurality of partial-products;
wherein an input terminal of the second register is operable to receive a first one of the plurality of partial-products based on a most significant bit (MSB) of the input signal; and
wherein an input terminal of the first register is operable to receive an output of the adder.

9. The device of claim 8, further comprising a third register having an input terminal that is operably connected to the output of the adder.

10. The device of claim 8, wherein the multiplier comprises a NOR gate.

11. The device of claim 8, wherein the multiplier comprises an AND gate.

12. The device of claim 8, further comprising a memory array configured to store the weight signal.

13. The device of claim 12, wherein the memory array includes a plurality of SRAM cells.

14. The device of claim 8, further comprising a memory array configured to store the weight signal.

15. The device of claim 8, wherein the multiplier is configured to determine the first one of the partial-products by multiplying the MSB I[N] (N>0) of the input by each bit of the weight signal.

16. The device of claim 15, wherein:
the shifter is configured to left-shift a first partial sum based on the first one of the partial products one bit;
the multiplier is configured to determine a second one of the partial-products by multiplying the next bit I[N−1] of the input signal by each bit of the weight signal; and
the adder is configured to add the left-shifted first partial sum and the second one of the partial-products to obtain a second partial-sum of the next bit I[N−1].

17. The device of claim 16, wherein:
the shifter is configured to left-shift the obtained second partial sum of the next bit I[N−1] one bit;
the multiplier is configured to determine the next one of the partial-products of the LSB I[0] of the input signal by multiplying the LSB I[0] of the input signal by each bit of the weight signal; and
the adder is configured to add the obtained left-shifted second partial-sum of the next bit I[N−1] and the next one of the partial-products of the LSB I[0] to obtain the total-sum.

18. A device, comprising:
a memory array storing a weight signal;
an input driver configured to output an input signal;
a multiplier configured to perform a bit-serial multiplication of the input signal and the weight signal, from a most significant bit (MSB) of the input signal to a least significant bit (LSB) of the input signal to determine a plurality of partial-products;
a shifter configured to left-shift a first partial-sum of a first bit of the input signal one bit;
an adder configured to add the left-shifted first partial-sum and a second partial-product of a second bit of the input signal to obtain a second partial-product of the second bit, wherein the second bit is one bit after the first bit.

19. The device of claim 18, further comprising:
a first register having an output terminal operably connected to an input terminal of the shifter and an input terminal operably connected to an output of the adder;
a second register having an output terminal operably connected to a second input terminal of the adder, wherein an input terminal of the second register is operably connected to an output terminal of the multiplier.

20. The device of claim 19, further comprising a third register having an input terminal that is operably connected to the output of the adder.
